(19) United States
(12) Patent Application Publication
(10) Pub. No.: US 2016/0256962 A1
(43) Pub. Date: Sep. 8, 2016

(54) LEAD-FREE SOLDER HAVING LOW MELTING POINT

(71) Applicant: MK Electron Co., Ltd., Gyeonggi-do (KR)

(72) Inventors: Hui Joong KIM, Seoul (KR); Jae Hun SONG, Gyeonggi-do (KR); Young Woo LEE, Gyeonggi-do (KR); Jae Hong LEE, Seoul (KR); Jae Yeol SON, Gyeonggi-do (KR); Eung Jae KIM, Daegu (KR); Ho Gun CHA, Daejeon (KR)

(73) Assignee: MK Electron Co., Ltd., Gyeonggi-do (KR)

(21) Appl. No.: 15/044,585

(22) Filed: Feb. 16, 2016

(30) Foreign Application Priority Data
Mar. 3, 2015 (KR) 10-2015-0029851

(51) Int. Cl. B23K 35/26; C22C 13/02; B23K 35/362; H01L 23/00; B23K 35/02

(52) U.S. Cl. CPC B23K 35/262; H01L 24/13; B23K 35/0244; B23K 35/362; C22C 13/02; B23K 35/025; H01L 2224/13111; H01L 2224/13113; H01L 2224/13109; H01L 2224/13139; H01L 2224/13155; H01L 2224/13147; H01L 2224/13014

(57) ABSTRACT

A solder ball includes about 1.0 wt % to about 2.0 wt % silver (Ag), about 4.0 wt % to about 8.0 wt % indium (In), about 10.0 wt % to about 20.0 wt % bismuth (Bi), about 0.005 wt % to about 0.1 wt % deoxidizer, and the balance of tin (Sn). A melting point of the solder is about 170° C. to about 190° C.

### CROSS-REFERENCE TO RELATED APPLICATION

This application claims the benefit of Korean Patent Application No. 10-2015-0029851, filed on Mar. 3, 2015, in the Korean Intellectual Property Office, the disclosure of which is incorporated herein in its entirety by reference.

### BACKGROUND

1. Field

One or more embodiments relate to a solder having a low melting point, and more particularly, to a lead-free solder ball having a low melting point, which exhibits superior thermal reliability, without using lead, as a solder, particularly a solder ball, that may be used to bond a substrate and a semiconductor package.

2. Description of the Related Art

With the recent trend toward high performance miniaturized electronic apparatuses, there is demand for miniaturization of a package at an assembly level of the electronic apparatuses. Accordingly, instead of a lead frame according to the related art, solder balls are used for miniaturization of a package. The solder balls may perform functions of bonding a substrate and a package and transmitting a signal of a chip in the package to the substrate. Recently, lead-free solder balls have been applied to semiconductor packages. Although the lead-free solder balls exhibit superior electrical conductivity, there is much room for improvement in terms of thermal reliability.

### SUMMARY

One or more embodiments include a lead-free solder ball having a low melting point, which has a low melting point and exhibits superior thermal reliability, without using lead.

One or more embodiments include a semiconductor package including lead-free solder ball having a low melting point, which has a low melting point and exhibits superior thermal reliability, without using lead.

Additional aspects will be set forth in part in the description which follows and, in part, will be apparent from the description, or may be learned by practice of the presented embodiments.

According to one or more embodiments, a solder includes about 1.0 wt % to about 2.0 wt % silver (Ag), about 4.0 wt % to about 8.0 wt % indium (In), about 10.0 wt % to about 20.0 wt % bismuth (Bi), about 0.005 wt % to about 0.1 wt % deoxidizer, and the balance of tin (Sn), in which a melting point of the solder is about 170° C. to about 190° C.

The solder may further include about 0.02 wt % to about 0.1 wt % nickel (Ni).

The solder may further include about 0.3 wt % to about 0.9 wt % copper (Cu).

The deoxidizer may be a metal selected from the group consisting of aluminum (Al), silicon (Si), manganese (Mn), titanium (Ti), and lithium (Li).

The deoxidizer may be aluminum (Al).

According to one or more embodiments, a solder ball manufactured of the solder having a composition of about 1.0 wt % to about 2.0 wt % silver (Ag), about 4.0 wt % to about 8.0 wt % indium (In), about 10.0 wt % to about 20.0 wt % bismuth (Bi), about 0.005 wt % to about 0.1 wt % deoxidizer, and the balance of tin (Sn).

According to one or more embodiments, a solder powder manufactured of the solder having a composition of about 1.0 wt % to about 2.0 wt % silver (Ag), about 4.0 wt % to about 8.0 wt % indium (In), about 10.0 wt % to about 20.0 wt % bismuth (Bi), about 0.005 wt % to about 0.1 wt % deoxidizer, and the balance of tin (Sn).

According to one or more embodiments, a solder paste manufactured of the solder having a composition of about 1.0 wt % to about 2.0 wt % silver (Ag), about 4.0 wt % to about 8.0 wt % indium (In), about 10.0 wt % to about 20.0 wt % bismuth (Bi), about 0.005 wt % to about 0.1 wt % deoxidizer, and the balance of tin (Sn).

According to one or more embodiments, a semiconductor package includes a solder ball, the solder ball including about 1.0 wt % to about 2.0 wt % silver (Ag), about 4.0 wt % to about 8.0 wt % indium (In), about 10.0 wt % to about 20.0 wt % bismuth (Bi), about 0.005 wt % to about 0.1 wt % deoxidizer, and the balance of tin (Sn), in which a melting point of the solder is about 170° C. to about 190° C.

The solder ball may further include about 0.02 wt % to about 0.1 wt % nickel (Ni).

The solder ball may further include about 0.3 wt % to about 0.9 wt % copper (Cu).

The deoxidizer may be a metal selected from the group consisting of aluminum (Al), silicon (Si), manganese (Mn), titanium (Ti), and lithium (Li).

### BRIEF DESCRIPTION OF THE DRAWINGS

These and/or other aspects will become apparent and more readily appreciated from the following description of the embodiments, taken in conjunction with the accompanying drawings in which:

FIG. 1 is a graph showing melting points according to an addition of bismuth, which were measured using a melting point tester;

FIG. 2 is a graph showing melting points according to an addition of indium, which were measured using a melting point tester;

FIGS. 3A and 3B are graphs showing wettability according to the addition of bismuth;

FIGS. 4A to 4D are graphs showing shearing strength during bonding of a semiconductor chip and a solder ball;

FIGS. 5A to 5C are graphs showing thicknesses of an intermetallic compound generated during the bonding of a semiconductor chip and a solder ball; and

FIGS. 6 to 8 schematically illustrate semiconductor packages including solder balls according to embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. Furthermore, various elements and regions are schematically illustrated in the accompanying drawings. Accordingly, the technical concept of the present inventive concept is not limited by relative sizes or intervals illustrated in the drawings. In embodiments, “wt %” (weight %) signifies a percentage of weight of a component with respect to the total weight of an alloy.

Terms such as “first” and “second” are used herein merely to describe a variety of constituent elements, but the constituent elements are not limited by the terms. Such terms are used only for the purpose of distinguishing one constituent element from another constituent element. For example, without departing from the right scope of the present inventive concept, a first constituent element may be referred to as a second constituent element, and vice versa.

Terms used in the present specification are used for explaining a specific embodiment, not for limiting the present inventive concept. Thus, an expression used in a singular form in the present specification also includes the expression in its plural form unless clearly specified otherwise in context. Also, terms such as “include” or “comprise” may be construed to denote a certain characteristic, number, step, operation, constituent element, or a combination thereof, but may not be construed to exclude the existence of or a possibility of addition of one or more other characteristics, numbers, steps, operations, constituent elements, or combinations thereof.

Unless defined otherwise, all terms used herein including technical or scientific terms have the same meanings as those generally understood by those of ordinary skill in the art to which the present inventive concept may pertain. The terms as those defined in generally used dictionaries are construed to have meanings matching that in the context of related technology and, unless clearly defined otherwise, are not construed to be ideally or excessively formal.

As used herein, expressions such as “at least one of,” when preceding a list of elements, modify the entire list of elements and do not modify the individual elements of the list.

The present inventive concept relates to a lead-free solder having a low melting point including tin (Sn), silver (Ag), indium (In), and bismuth (Bi), that is, about 1.0 wt % to about 2.0 wt % silver, about 4.0 wt % to about 8.0 wt % indium, about 10.0 wt % to about 20.0 wt % bismuth, about 0.005 wt % to 0.1 wt % deoxidizer, and the balance including tin with respect to the total weight of the solder.

The indium exhibits thermal fatigue resistance and increases flowability of a solder to thus improve solderability. According to the present inventive concept, by adding indium, wettability of a solder may be improved and simultaneously soldering is available at a temperature similar to a temperature at which soldering using a tin (Sn)-lead (Pb) based solder including lead according to a related art is performed. In other words, by lowering a melting point so that low-temperature soldering is available, damage to electronic parts that are bonding base members due to heat shock may be reduced. Furthermore, when thermal expansion coefficients between bonded structures are not matched, ductility that is a standard for accommodating the mismatch is increased so that mechanical properties may be improved.

The bismuth lowers a melting point of tin. The bismuth may be about 10 wt % to 20 wt % of the total weight of a lead-free solder composite. In this state, if a content of bismuth is less than about 10 wt %, the melting point of tin may not be lowered and wettability may be hardly improved. If the content of bismuth exceeds about 20 wt %, which is out of a process temperature range, brittleness and an increase in a solidification range occurs so that physical properties may be degraded. Also, wettability may be deteriorated.

The tin forms the balance of the lead-free solder composite, and the content of tin is relatively determined by a content of other components. Furthermore, although the lead-free solder composite according to the present embodiment exhibits superior mechanical properties, the lead-free solder composite may further include at least one type of metal selected from nickel (Ni) and copper (Cu) to further reinforce the mechanical properties.

The nickel and copper are used to increase bonding strength by growing an intermetallic compound (IMC) on an interface between a pad of a semiconductor chip and a solder ball when the solder ball used for boning the semiconductor chip and the substrate is manufactured.

In the present embodiment, the deoxidizer may be a metal selected from aluminum (Al), silicon (Si), manages (Mn), titanium (Ti), and lithium (Li). In particular, in the present embodiment, the deoxidizer may be aluminum (Al).

In the following description, the structure and effect of the present inventive concept are described in detail with specific comparative examples and experimental examples. However, the experimental examples are merely to make the present inventive concept more clearly understood, not limiting the scope of the present inventive concept. In the comparative examples and experimental examples, physical properties are evaluated by the following method.

[Solder Ball]

A lead-free solder alloy according to the present embodiment was manufactured by constantly cutting tin (Sn), silver (Ag), indium (In), bismuth (Bi), nickel (Ni), and copper (Cu), which were materials having a purity of more than about 99.9%, and cleaning the materials using ethanol. The cleaned specimens were inserted into a melting bath according to a weight ratio (added at a weight ratio of each material with respect to 1 kg), and kept for about one hour at a temperature of about 500° C. Then, melted solder is poured into a mold to manufacture a bar-type solder alloy. A melting point and wettability were analyzed using the bar-type solder alloy.

To measure a melting point of the manufactured alloy, melting points according to composition of the solder were measured using a differential scanning calorimetry (DSC). Furthermore, wettability was evaluated using a wetting balance tester SAT-5000. A copper plate having a degree of purity of more than about 99.9% and a size of 30×20×0.3 (mm) was used as a specimen for the wettability test. To remove foreign materials such as an oxidation film existing on a surface of the specimen, the specimen was first ultrasonic cleaned in an acetone solution. The ultrasonic cleaned specimen was dipped into a diluted hydrochloric acid solution and cleaned with ethanol. An RMA type flux was coated on the cleaned specimen and hung on a holder. While the specimen on the holder was kept still, a solder bath disposed under the specimen ascended. When the solder bath contacted the specimen, measurement started. In this state, a temperature of the solder bath was determined considering a melting temperature of each solder. The temperature of the solder bath in the present embodiment was set to about 240° C. When a lower end portion of the specimen reached a preset dipping depth, the solder bath paused for a set time and then descended.

In the present embodiment, the dipping depth, the dipping speed, and the dipping time of a specimen were respectively set to about 10 mm, about 5 mm/sec, and about 5 sec. The wettability of the specimen measured as above was converted into newton (N) for measurement. The wettability was analyzed in a zero-cross time manner.

The measurement of a change in the wettability properties with respect to a lead-free solder alloy according to the experimental example is a generally used wetting balance test method. Such a test method has been introduced in EIAJ ET-7404, IEC 600068-2-54, MIL-STD883C, KS CO236 that is a standard of the Electronic Industries Association of Japan, and called a Meniscograph method. According to the method, a solder of a particular size is put into a solder bath and heated to a set temperature, and then, a copper plate is dipped into the solder bath. Accordingly, a floating force and wetting force applied to a test specimen are measured so that an acting force to a time curve is analyzed to evaluate wettability. In the method, a wetting balance tester SAT-5000 is used for measurement.

TABLE 1

| | | | | | | | Melting |
|---|---|---|---|---|---|---|---|
| | Sn | Ag | In | Bi | Cu | Ni | point |
| | (wt %) | (wt %) | (wt %) | (wt %) | (wt %) | (wt %) | (° C.) |
| Comparative | the balance | 2 | | | | | 231 |
| example 1 | | | | | | | |
| Experimental | the balance | 2 | | 1 | | | 220 |
| example 1 | | | | | | | |
| Experimental | the balance | 2 | | 5 | | | 207 |
| example 2 | | | | | | | |
| Experimental | the balance | 2 | | 10 | | | 200 |
| example 3 | | | | | | | |
| Experimental | the balance | 2 | | 16 | | | 192 |
| example 4 | | | | | | | |
| Experimental | the balance | 2 | | 20 | | | 187 |
| example 5 | | | | | | | |

1. Change in Melting Point According to Bismuth Content

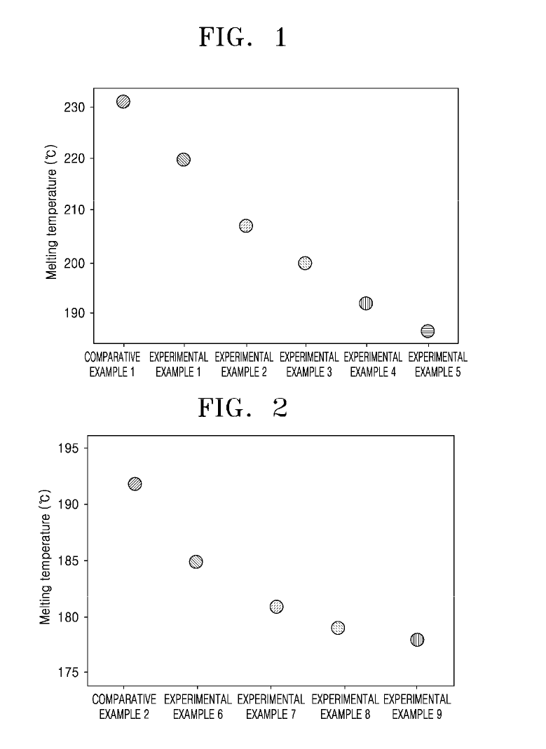

Referring to Table 1 and FIG. 1, melting points of specimens of comparative examples and experimental examples were analyzed using a melting point tester. A test was performed by increasing an addition amount of bismuth using Sn-2Ag (tin containing 2 wt % silver) as a base. As illustrated in FIG. 1, it may be seen that, as an addition amount of bismuth increases, a melting point decreases.

A change in the melting point according to the addition of bismuth was measured to be: 231° C. when the addition amount of bismuth was 0 wt % as in Comparative example 1, 220° C. when the addition amount of bismuth was 1 wt % as in Experimental example 1, 207° C. when the addition amount of bismuth was 5 wt % as in Experimental example 2, 200° C. when the addition amount of bismuth was 10 wt % as in Experimental example 3, 192° C. when the addition amount of bismuth was 16 wt % as in Experimental example 4, and 187° C. when the addition amount of bismuth was 20 wt % as in Experimental example 4.

As illustrated in FIG. 1, as the addition amount of bismuth increases, the melting point decreases. However, it may be seen that, as a decrease range of the melting point increases, a variation width of the melting point increases even by a small addition amount of bismuth.

In consideration of a result of the above experiment, when a content of bismuth is more than 16 wt %, a melting point reduction effect is not much. Rather, brittleness increases greatly. Thus, the 16 wt % bismuth is determined to be an optimal condition.

TABLE 2

| | Sn | Ag | In | Bi | Cu | Ni | Melting point |
|---|---|---|---|---|---|---|---|
| | (wt %) | (wt %) | (wt %) | (wt %) | (wt %) | (wt %) | (° C.) |
| Comparative | the balance | 2 | | 16 | | | 192 |
| example 2 | | | | | | | |
| Experimental | the balance | 2 | 4 | 16 | | | 185 |
| example 6 | | | | | | | |
| Experimental | the balance | 2 | 6 | 16 | | | 181 |
| example 7 | | | | | | | |
| Experimental | the balance | 2 | 8 | 16 | | | 179 |
| example 8 | | | | | | | |
| Experimental | the balance | 2 | 10 | 16 | | | 178 |
| example 9 | | | | | | | |

2. Change in Melting Point According to Indium Content

Referring to Table 2 and FIG. 2, melting points of specimens of comparative examples and experimental examples were analyzed using a melting point tester. A test was performed by increasing an addition amount of indium using Sn-2Ag-16Bi (tin containing 2 wt % silver and 16 wt % bismuth) as a base. As illustrated in FIG. 2, it may be seen that, as an addition amount of indium increases, a melting point decreases.

A change in the melting point according to the addition of indium was measured to be: 192° C. when the addition amount of indium was 0 wt % as in Comparative example 2, 185° C. when the addition amount of indium was 4 wt % as in Experimental example 6, 181° C. when the addition amount of indium was 6 wt % as in Experimental example 7, 179° C. when the addition amount of indium was 8 wt % as in Experimental example 8, and 178° C. when the addition amount of indium was 10 wt % as in Experimental example 9.

In consideration of a result of the above experiment, it may be seen that not much change is expected in the melting point by adding indium of 6 wt % or more.

TABLE 3

| | Sn | Ag | In | Bi | Cu | Ni | Zero-cross time |
|---|---|---|---|---|---|---|---|
| | (wt %) | (wt %) | (wt %) | (wt %) | (wt %) | (wt %) | (sec) |
| Comparative | the balance | 2 | | | | | 0.77 |
| example 1 | | | | | | | |
| Experimental | the balance | 2 | | 1 | | | 0.75 |
| example 1 | | | | | | | |
| Experimental | the balance | 2 | | 5 | | | 0.71 |
| example 2 | | | | | | | |
| Experimental | the balance | 2 | | 10 | | | 0.51 |
| example 3 | | | | | | | |
| Experimental | the balance | 2 | | 16 | | | 0.48 |
| example 4 | | | | | | | |
| Experimental | the balance | 2 | | 20 | | | 0.44 |
| example 5 | | | | | | | |
| Experimental | the balance | 2 | 4 | 16 | | | |
| example 6 | | | | | | | |
| Experimental | the balance | 2 | 6 | 16 | | | 0.49 |
| example 7 | | | | | | | |
| Experimental | the balance | 2 | 8 | 16 | | | |
| example 8 | | | | | | | |
| Experimental | the balance | 2 | 10 | 16 | | | |
| example 9 | | | | | | | |
| Experimental | the balance | 2 | 6 | 16 | 0.7 | | 0.40 |
| example 10 | | | | | | | |
| Experimental | the balance | 2 | 6 | 16 | | 0.05 | 0.51 |
| example 11 | | | | | | | |

3. Change in Wettability According to Bismuth Content

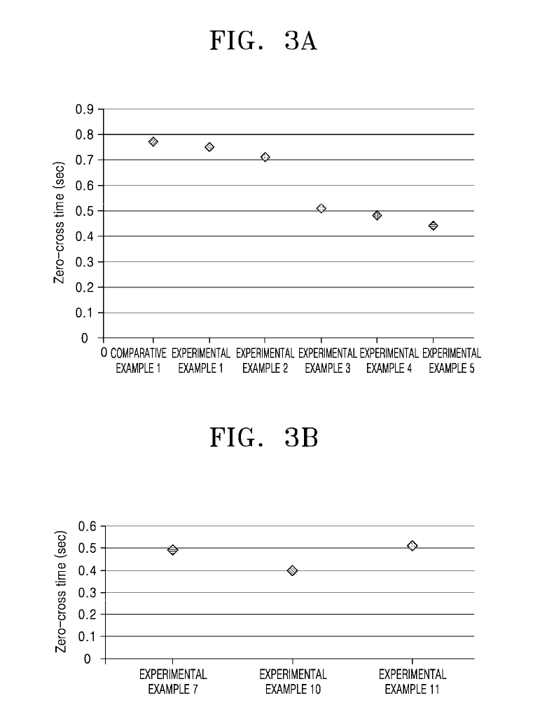

Referring to Table 3 and FIG. 3A, a change in wettability according to addition of bismuth was measured such that: a zero-cross time was about 0.77 sec when the addition amount of bismuth was 0 wt % as in Comparative example 1, a zero-cross time was about 0.75 sec when the addition amount of bismuth was 1 wt % as in Experimental example 1, a zero-cross time was about 0.71 sec when the addition amount of bismuth was 5 wt % as in Experimental example 2, a zero-cross time was about 0.51 sec when the addition amount of bismuth was 10 wt % as in Experimental example 3, a zero-cross time was about 0.48 sec when the addition amount of bismuth was 16 wt % as in Experimental example 4, and a zero-cross time was about 0.44 sec when the addition amount of bismuth was 20 wt % as in Experimental example 5.

In consideration of a result of the above experiment, it may be seen that not much change is expected in the wettability by adding bismuth of 10 wt % or more.

Also, referring to Table 3 and FIG. 3B, in Experimental example 7 showing an optimal condition in the above melting point experiment, a zero-cross time was measured to be about 0.49 sec. In Experimental example 10, in which 0.7 wt % copper is added to Sn-2Ag-6In-16Bi that is a condition of Experimental example 7, a zero-cross time was measured to be about 0.40 sec, which is determined to show the most superior wettability. In Experimental example 11, in which 0.05 wt % nickel is added to Sn-2Ag-6In-16Bi that is the condition of Experimental example 7, a zero-cross time was measured to be about 0.51 sec

4. Shearing Strength

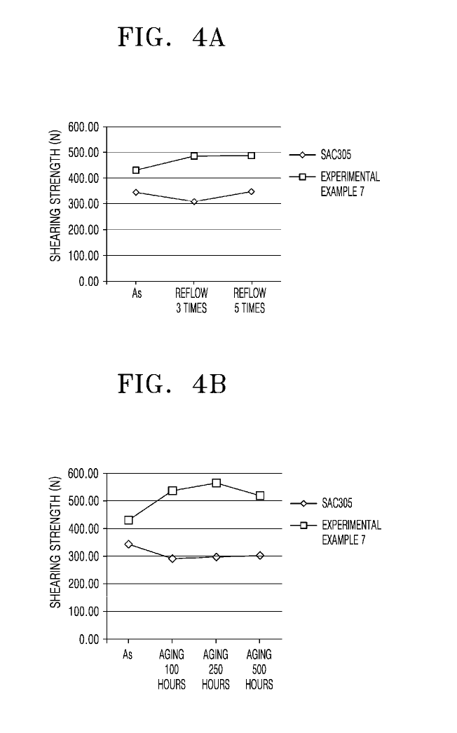

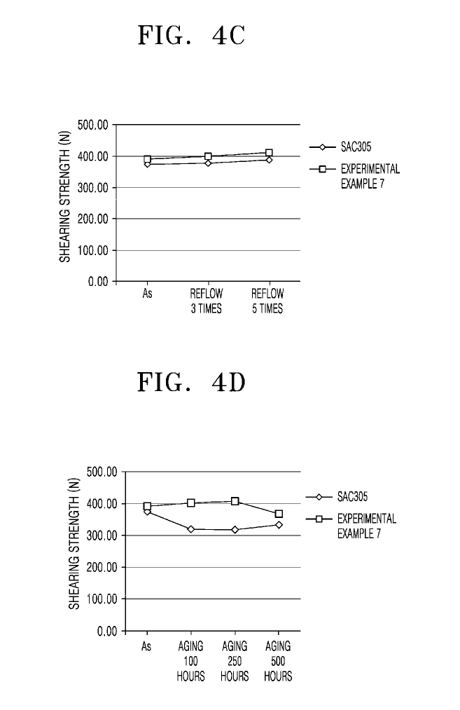

Referring to Table 3 and FIG. 4, Experimental example 7 showing an optimal condition in the melting point experiment according to the present inventive concept was compared with Sn-3Ag-0.5Cu (SAC305) that has been commonly used. A solder ball manufactured of a pad of a semiconductor chip and the solder of the experimental example 7 was bonded by coating a water-soluble flux on a printed circuit board (PCB) where the semiconductor chip is mounted, placing a solder ball on the PCB, and applying heat for 40 seconds at 245° C. in a reflow furnace capable of adjusting temperature and time. A unit used for the measurement of shearing strength is newton (N).

FIGS. 4A and 4B illustrate shearing strength measured after a cupper-organic solderability preservatives (Cu-OSP) pad of a semiconductor chip and the solder ball are bonded. As illustrated in FIG. 4A, Experimental example 7 shows superior shearing strength compared with the comparative example in the measurements performed right after the bonding and after performing multi-reflow three and five times. Furthermore, as illustrated in FIG. 4B, Experimental example 7 shows superior shearing strength compared with the comparative example in the measurements performed right after the bonding and after performing aging for 100, 250, and 500 hours at 125° C.

FIGS. 4C and 4D show shearing strength measured after a Ni/Au pad of a semiconductor chip and a solder ball are bonded. As illustrated in FIG. 4C, Experimental example 7 shows superior shearing strength compared with the comparative example in the measurements performed right after the bonding and after performing multi-reflow three and five times. Furthermore, as illustrated in FIG. 4D, Experimental example 7 shows superior shearing strength compared with the comparative example in the measurements performed right after the bonding and after performing aging for 100, 250, and 500 hours at 125° C.

5. Intermetallic Compound of Bonding Interface

An intermetallic compound of a bonding interface, which is a measure indicating chemical bonding between metals, increases bonding strength. However, when the intermetallic compound is formed thick, the intermetallic compound may cause cracks in the bonding interface. Accordingly, although the formation of the intermetallic compound may increase bonding strength, it is determined that a thin thickness of the intermetallic compound is preferred.

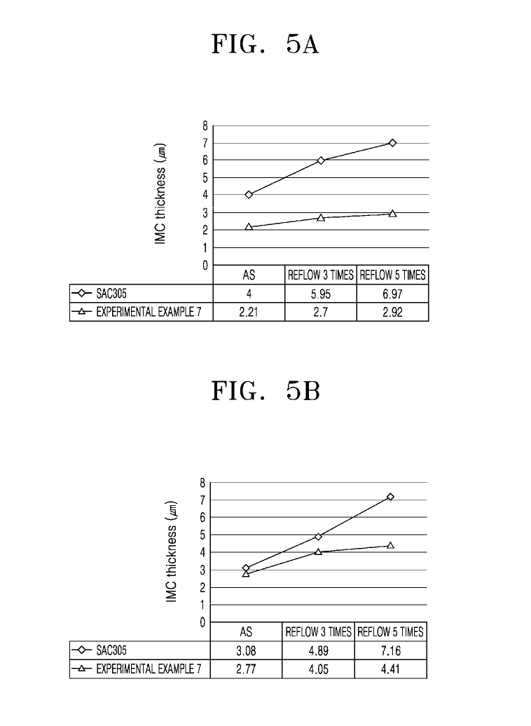

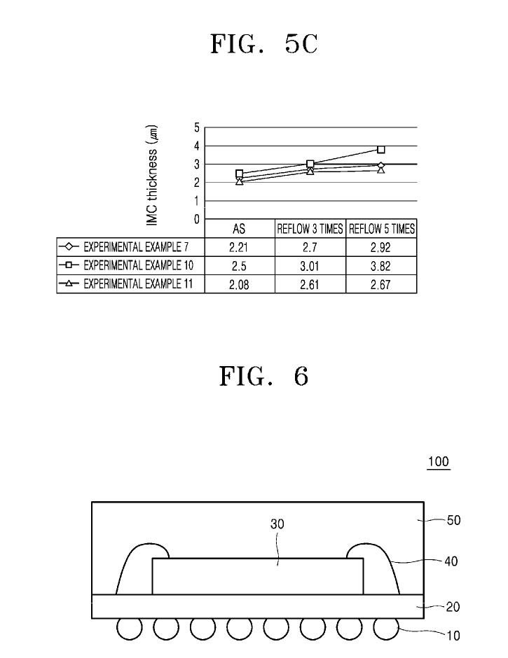

Referring to Table 1 and FIG. 5, Experimental example 7 showing an optimal condition in the melting point experiment according to the present inventive concept was compared with Sn-3Ag-0.5Cu that has been commonly used. A solder ball manufactured of a pad of a semiconductor chip and the solder of the experimental example 7 was bonded by coating a water-soluble flux on a PCB, placing a solder ball on the PCB, and applying heat for 40 seconds at 245° C. in a reflow furnace capable of adjusting temperature and time. The thickness of the intermetallic compound of a bonding interface generated between the pad of a semiconductor chip and the solder ball was measured using an Auger electron spectroscopy.

As illustrated in FIG. 5A, in the case of a Cu-OSP pad of a semiconductor chip, an intermetallic compound having a thin interface, compared with Sn-3Ag-0.5Cu, is grown in Experimental example 7. In particular, a stable thickness of the intermetallic compound is shown after performing multi-reflow three times and five times. Also, it is shown that a growth speed is slow.

As illustrated in FIG. 5B, in the case of a Ni/Au pad of a semiconductor chip, at initial bonding, an intermetallic compound having a thickness similar to that of Sn-3Ag-0.5Cu is grown in Experimental example 7. However, it is observed that, after performing multi-reflow three times and five times, the intermetallic compound is grown to be thin compared with Sn-3Ag-0.5Cu.

As illustrated in FIG. 5C, in the case of a Cu-OSP pad of a semiconductor chip, an intermetallic compound having a thin interface is grown in Experimental examples 7, 10, and 11. In particular, a stable thickness of the intermetallic compound is shown after performing multi-reflow three times and five times. Also, it is shown that a growth speed is slow. In particular, when nickel of Experimental example 11 is added by 0.05%, a result of the addition is similar to Experimental example 7 after the bonding and performing multi-reflow three times. However, after performing multi-reflow five times, the growth of an intermetallic compound is slow compared with Experimental examples 7 and 10. Accordingly, it is determined that bonding properties are superior when a small amount of nickel is added.

As described above, compared with a Sn—Ag—Cu based lead-free solder alloy according to a related art, an amount of silver used is remarkably reduced so that an effect of reducing raw costs may be obtained. Furthermore, although strength and wettability of a solder are generally improved by adding bismuth, elongation and aging resistance are deteriorated and thermal fatigue properties are degraded. However, aging resistance and elongation are improved by adding indium at an optimal content ratio. Also, since a melting point is lowered, a lead-free solder alloy having superior mechanical properties of a solder, such as strength, wettability, and shearing strength, and high reliability may be manufactured.

[Semiconductor Package]

FIGS. 6 to 8 schematically illustrate semiconductor packages 100, 200, and 300 including solder balls 10 according to embodiments.

Referring to FIG. 6, the semiconductor package 100 according to the present embodiment may include the solder ball 10. The semiconductor package 100 may include a printed circuit board 20, a semiconductor chip 30 disposed on the printed circuit board 20, a bonding wire 40 electrically connecting the semiconductor chip 30 to the printed circuit board 20, and an encapsulation member 50 hermetically sealing the semiconductor chip 30 and the bonding wire 40. The solder ball 10 is attached on a lower surface of the printed circuit board 20 and electrically connected to the semiconductor chip 30 via the printed circuit board 20. In this state, although the semiconductor package 100 is illustrated as having one semiconductor chip 30, the present disclosure is not limited thereto and the semiconductor package 100 may include a plurality of semiconductor chips.

Referring to FIG. 7, the semiconductor package 200 according to the present embodiment may include the solder ball 10. The semiconductor package 200 may include the printed circuit board 20, the semiconductor chip 30 disposed on the printed circuit board 20, an inner solder ball 10a electrically connecting the semiconductor chip 30 to the printed circuit board 20, and the encapsulation member 50 hermetically sealing the semiconductor chip 30. The solder ball 10 is attached on the lower surface of the printed circuit board 20 and electrically connected to the semiconductor chip 30 via the printed circuit board 20. The inner solder ball 10a may include materials of the same contents as those of the solder ball 10. The inner solder ball 10a may have a small size, compared with the solder ball 10. In this state, although the semiconductor package 200 is illustrated as having one semiconductor chip 30, the present disclosure is not limited thereto and the semiconductor package 200 may include a plurality of semiconductor chips.

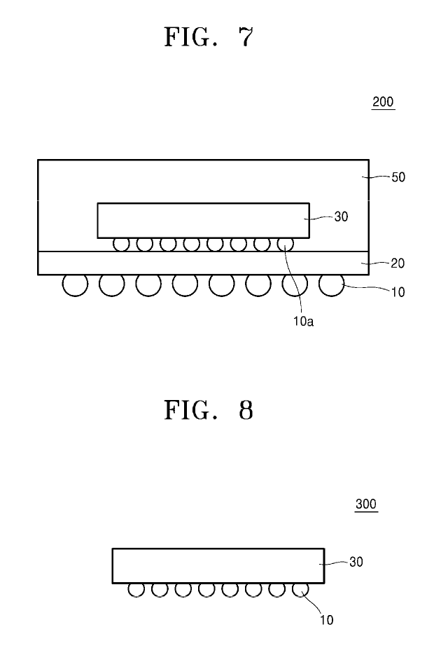

Referring to FIG. 8, the semiconductor package 300 according to the present embodiment may include the solder ball 10. The semiconductor package 300 may include the semiconductor chip 30 and the solder ball 10 attached on a lower surface of the semiconductor chip 30 and electrically connected to the semiconductor chip 30. The semiconductor chip 30 may be a system-on-chip (SOC) or a system-in-package (SIP). In this state, although the semiconductor package 300 is illustrated as having one semiconductor chip 30, the present disclosure is not limited thereto and the semiconductor package 300 may include a plurality of semiconductor chips.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. A solder comprising:
about 1.0 wt % to about 2.0 wt % silver (Ag);
about 4.0 wt % to about 8.0 wt % indium (In);
about 10.0 wt % to about 20.0 wt % bismuth (Bi);
about 0.005 wt % to about 0.1 wt % deoxidizer; and
the balance of tin (Sn),
wherein a melting point of the solder is about 170° C. to about 190° C.

2. The solder of claim 1, further comprising about 0.02 wt % to about 0.1 wt % nickel (Ni).

3. The solder of claim 1, further comprising about 0.3 wt % to about 0.9 wt % copper (Cu).

4. The solder of claim 1, wherein the deoxidizer is a metal selected from the group consisting of aluminum (Al), silicon (Si), manganese (Mn), titanium (Ti), and lithium (Li).

5. The solder of claim 4, wherein the deoxidizer is aluminum (Al).

6. A solder ball manufactured of the solder having a composition according to the claim 1.

7. A solder powder manufactured of the solder having a composition according to the claim 1.

8. A solder paste manufactured of the solder having a composition according to the claim 1.

9. A semiconductor package comprising a solder ball, the solder ball comprising:
about 1.0 wt % to about 2.0 wt % silver (Ag);
about 4.0 wt % to about 8.0 wt % indium (In);
about 10.0 wt % to about 20.0 wt % bismuth (Bi);
about 0.005 wt % to about 0.1 wt % deoxidizer; and
the balance of tin (Sn),
wherein a melting point of the solder is about 170° C. to about 190° C.

10. The semiconductor package of claim 9, wherein the solder ball further comprises about 0.02 wt % to about 0.1 wt % nickel (Ni).

11. The semiconductor package of claim 9, wherein the solder ball further comprises about 0.3 wt % to about 0.9 wt % copper (Cu).

12. The semiconductor package of claim 9, wherein the deoxidizer is a metal selected from the group consisting of aluminum (Al), silicon (Si), manganese (Mn), titanium (Ti), and lithium (Li).
